(19) United States
(12) Patent Application Publication
(10) Pub. No.: US 2025/0157897 A1
(43) Pub. Date: May 15, 2025

(54) SEMICONDUCTOR MODULE

(71) Applicant: FUJI ELECTRIC CO., LTD., Kawasaki-shi (JP)

(72) Inventor: Yuhei NISHIDA, Kawasaki-shi (JP)

(73) Assignee: FUJI ELECTRIC CO., LTD., Kawasaki-shi (JP)

(21) Appl. No.: 18/820,990

(22) Filed: Aug. 30, 2024

(30) Foreign Application Priority Data
Nov. 10, 2023 (JP) 2023-191901

(51) Int. Cl. H01L 23/495

(52) U.S. Cl. CPC H01L 23/49568; H01L 23/49513; H01L 23/49537; H01L 23/49548

(57) ABSTRACT

A semiconductor module includes wiring boards on each of which at least one semiconductor element is mounted, a heat dissipation base to which each wiring board is bonded via a first bonding material. The heat dissipation base is warped to be convex away from the semiconductor element. The first surface of the heat dissipation base has a rectangular wiring board area with four corner portions in which all the wiring boards are bonded. The plurality of corner wiring boards include a plurality of corner wiring boards that includes a plurality of first corner portions bonded to the heat dissipation base with the first bonding material and four second corner portions not bonded to the heat dissipation base. The corner wiring boards are disposed such that the four second corner portions are respectively located at positions corresponding to respective ones of the four corners of the wiring board area.

### CROSS-REFERENCE TO RELATED APPLICATION

This application is based upon and claims the benefit of priority to Japanese Patent Application No. 2023-191901, filed on Nov. 10, 2023, the entire contents of which are incorporated herein by reference.

### BACKGROUND OF THE INVENTION

### 1. Technical Field

The present invention relates to a semiconductor module including a plurality of wiring boards on which a semiconductor element is mounted and a heat dissipation base to which the plurality of wiring boards are bonded.

### 2. Description of the Related Art

There is a semiconductor module used in a power conversion device such as an inverter device in which a heat dissipation base bonded to a wiring board is attached to a cooler (for example, refer to JP 2020-141023 A, JP 2015-72958 A, JP 2015-72957 A, JP 2004-134746 A, JP 2021-90030 A, JP 2017-79217 A, and JP 2017-120888 A). As a heat dissipation base used in this type of semiconductor module, there is a heat dissipation base in which a second surface that faces the cooler and is on an opposite side of a first surface to which the wiring board is boned is molded to have a convex curved surface.

### SUMMARY OF THE INVENTION

The wiring board is bonded to the first surface of the heat dissipation base with a bonding material. When the heat dissipation base having the convex curved second surface is attached to the cooler, the second surface deforms in a direction in which the convex curved surface changes to a flat surface. Due to the deformation of the heat dissipation base, stress concentrates on the wiring board, which may damage the wiring board. To alleviate the stress of the wiring board, it is conceivable to reduce the area of bonding with the bonding material, but in this case, heat dissipation performance worsens.

In one aspect, an object of the present invention is to provide a semiconductor module capable of preventing damage to the wiring board due to deformation of the heat dissipation base when it is fastened, while securing the heat dissipation performance.

A semiconductor module according to one aspect includes: a plurality of wiring boards on which a semiconductor element is mounted; a heat dissipation base having a first surface to which the plurality of wiring boards are bonded and a second surface located on an opposite side of the first surface; and a first bonding material that bonds the plurality of wiring boards to the heat dissipation base, in which the heat dissipation base is warped such that the second surface becomes a convex curved surface, a fastening hole is provided at least at a plurality of corner portions of the heat dissipation base, a bonding surface facing the heat dissipation base of the wiring board of each of the plurality of wiring boards includes a first corner portion bonded to the heat dissipation base with the first bonding material and a second corner portion not bonded to the heat dissipation base with the first bonding material, and the first bonding material bonds the plurality of wiring boards to the heat dissipation base such that the second corner portion of the wiring board is located at four corners of a wiring board region including the entire area of the plurality of wiring boards.

According to the above aspect, it is possible to prevent damage to the wiring board due to deformation of the heat dissipation base when it is fastened, while securing the heat dissipation performance.

### BRIEF DESCRIPTION OF THE DRAWINGS

FIG. 1 is a plan view illustrating a semiconductor module according to a first embodiment;

FIG. 2 is a sectional view taken along line II-II in FIG. 1;

FIG. 3 is an explanatory view for explaining a warped shape of a second surface (lower surface) of a heat dissipation base in the first embodiment;

FIG. 4 is an explanatory view for explaining a local convex portion of the second surface of the heat dissipation base in the first embodiment;

FIG. 5 is a (first) circuit diagram example of the semiconductor module according to the first embodiment;

FIG. 6 is a (second) circuit diagram example of the semiconductor module according to the first embodiment;

FIG. 7A is a sectional view (part 1) illustrating a semiconductor module in a comparative example, which corresponds to the sectional view taken along line II-II in FIG. 1;

FIG. 7B is a sectional view (part 2) illustrating the semiconductor module in the comparative example, which corresponds to the sectional view taken along line II-II in FIG. 1;

FIG. 7C is a sectional view (part 3) illustrating the semiconductor module in the comparative example, which corresponds to the sectional view taken along line II-II in FIG. 1;

FIG. 8 is a plan view illustrating a semiconductor module according to a modification of the first embodiment;

FIG. 9 is a plan view illustrating a first bonding material of a wiring board according to the modification of the first embodiment in a see-through manner;

FIG. 10A is a sectional view (part 1) illustrating a semiconductor module according to a second embodiment, which corresponds to the sectional view taken along line II-II in FIG. 1;

FIG. 10B is a sectional view (part 2) illustrating the semiconductor module according to the second embodiment, which corresponds to the sectional view taken along line II-II in FIG. 1;

FIG. 11A is a sectional view (part 1) illustrating a semiconductor module according to a third embodiment, which corresponds to the sectional view taken along line II-II in FIG. 1;

FIG. 11B is a sectional view (part 2) illustrating the semiconductor module according to the third embodiment, which corresponds to the sectional view taken along line II-II in FIG. 1;

FIG. 12A is a sectional view (part 1) illustrating a semiconductor module according to a fourth embodiment, which corresponds to the sectional view taken along line II-II in FIG. 1; and

FIG. 12B is a sectional view (part 2) illustrating the semiconductor module according to the fourth embodiment, which corresponds to the sectional view taken along line II-II in FIG. 1.

### DETAILED DESCRIPTION

Hereinafter, semiconductor modules according to first to fourth embodiments of the present invention will be described with reference to the drawings. Note that each of X, Y, and Z axes in each drawing to be referred is indicated to define a direction or each plane in a semiconductor module or the like to be illustrated. The X, Y, and Z axes are orthogonal to each other and form a right-handed system. In the following description, the Z direction may be referred to as a vertical direction. Further, a plane including the X axis and the Y axis may be referred to as an upper surface or a lower surface. Such directions and planes are terms used for convenience of description. Thus, depending on a posture of attachment of the semiconductor module or the like, a correspondence relationship with the X, Y, and Z directions may vary. For example, here, a surface facing a Z direction front side (+Z direction) in a member forming the semiconductor module is referred to as a top surface, and a surface facing a Z direction negative side (−Z direction) is referred to as a bottom surface. However, the surface facing the Z direction negative side may be referred to as the top surface, and the surface facing the Z direction front side may be referred to as the bottom surface. Further, plan view herein means a case where an upper surface (XY plane) of the semiconductor module or the like is viewed from the positive side in the Z direction to the negative side in the Z direction.

An aspect ratio and a size relationship between the members in each drawing are merely schematically represented, and do not necessarily coincide with a relationship in the semiconductor module or the like actually manufactured. For convenience of description, the size relationship between the members may be exaggerated. Further, in different drawings, the shapes of the same member may be different.

In the following description, as an example of the semiconductor modules according to the embodiments and the energy conversion devices including these semiconductor modules, a device is exemplified that is applied to a power conversion device such as an industrial or an in-vehicle motor inverter device. Thus, in the following description, detailed description of the same or similar configuration, function, operation, assembly method, or the like as those of a known semiconductor module or energy conversion device will be omitted.

### First Embodiment

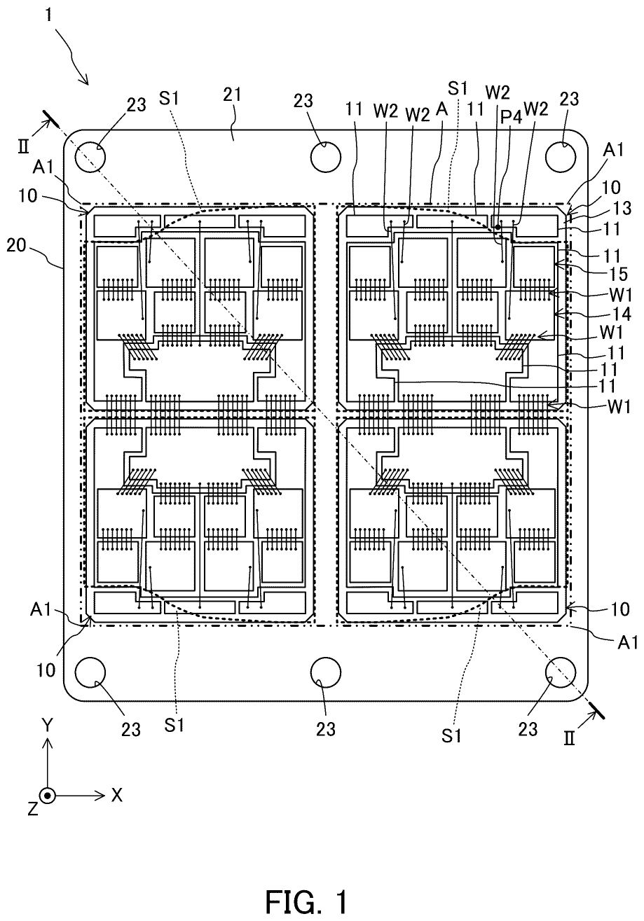

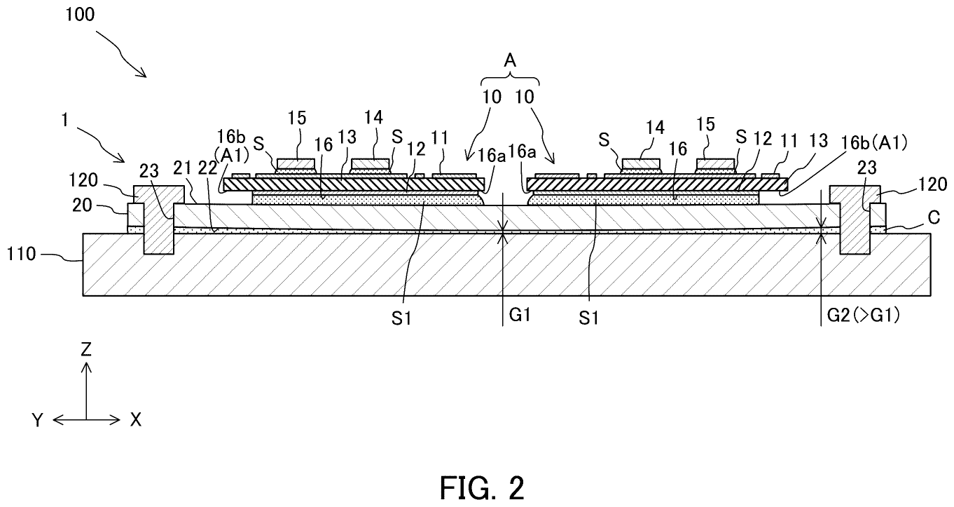

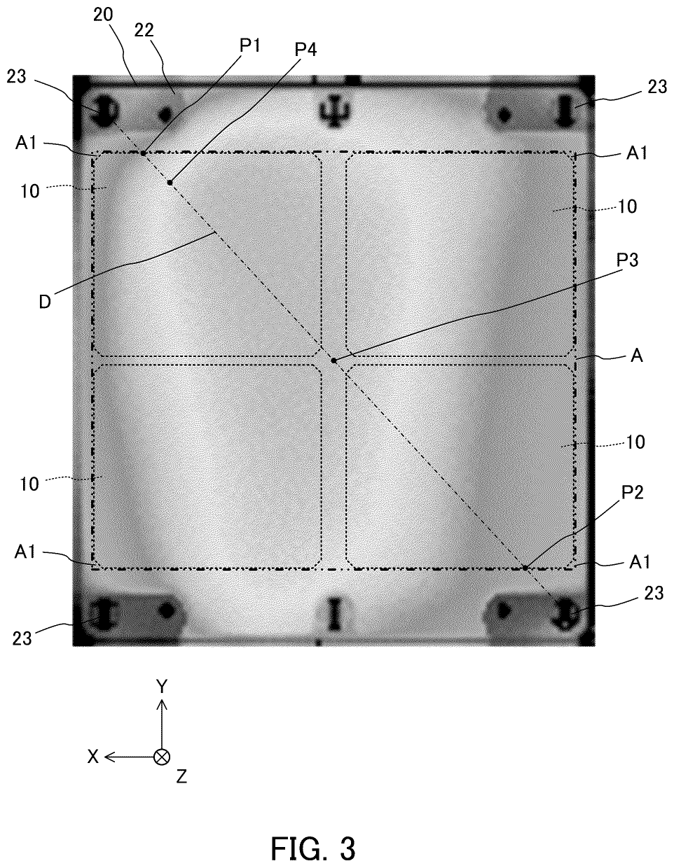

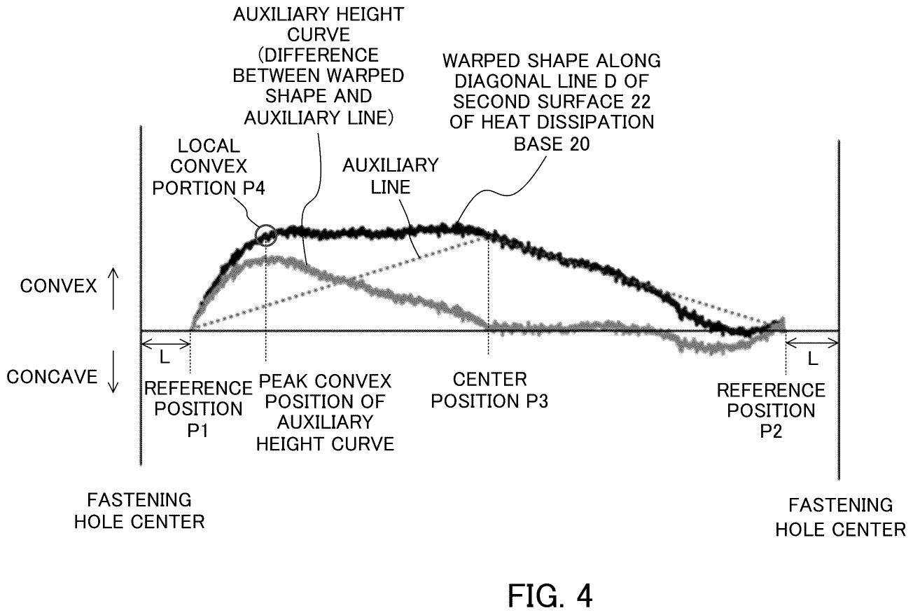

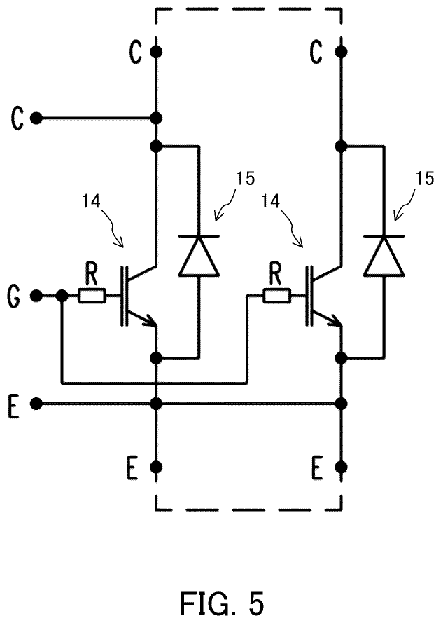

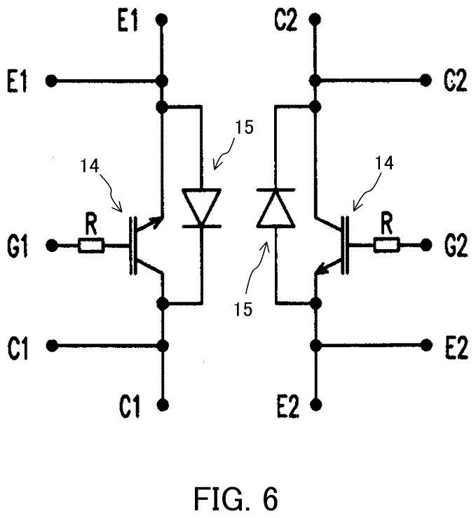

FIG. 1 is a plan view illustrating a semiconductor module 1. FIG. 2 is a sectional view taken along line II-II in FIG. 1. FIG. 3 is an explanatory view for explaining a warped shape of a second surface (lower surface) 22 of a heat dissipation base 20. FIG. 4 is an explanatory view for explaining a local convex portion P4 on the second surface 22. FIGS. 5 and 6 are circuit diagram examples of the semiconductor module 1. In FIGS. 1 and 3, a first bonding material S1 is indicated by a broken line (hidden line), and a wiring board region A is indicated by a two-dot chain line (imaginary line).

A semiconductor module 1 illustrated in FIGS. 1 and 2 includes a plurality of wiring boards 10, the heat dissipation base 20, and the first bonding material S1. An energy conversion device 100 illustrated in FIG. 2 includes the semiconductor module 1, a cooler 110, and a plurality of screws 120.

As illustrated in FIG. 2, the semiconductor module 1 is attached to the cooler 110 with the screw 120 inserted into a fastening hole 23 of the heat dissipation base 20. The screw 120 has a male screw to be screwed into a screw hole (female screw) of the cooler 110. The cooler 110 is, for example, a water jacket integrated type having a fin, a water jacket, and the like, or an open fin type having a fin exposed to the outside, or the like. The heat dissipation base 20 of the semiconductor module 1 and the cooler 110 are connected via a heat conductive material C such as thermal grease or thermal compound.

The plurality of (for example, four) wiring boards 10 are bonded to a first surface 21 (upper surface) of the common single heat dissipation base 20 at a bonding surface 16 which is the lower surface. The wiring board 10 includes a first conductor layer 11, a second conductor layer 12, and an insulating layer 13. The wiring board 10 can be, for example, a direct copper bonding (DCB) substrate or an active metal brazing (AMB) substrate. The wiring board 10 may be referred to as a laminated substrate, an insulating circuit board, an insulating heat dissipation circuit board, or the like.

The insulating layer 13 is, for example, a ceramic substrate. The insulating layer 13 is not limited to a specific substrate, but may be, for example, a ceramic substrate formed of a ceramic material such as aluminum nitride (AlN), aluminum oxide (Al₂O₃), silicon nitride (Si₃N₄), or a composite material of aluminum oxide (Al₂O₃) and zirconium oxide (ZrO₂). The insulating layer 13 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The second conductor layer 12 is a member that functions as a heat conducting member for conducting heat generated in the inverter circuit to the heat dissipation base 20 and is formed of, for example, a metal plate, a metal foil, or the like of copper, aluminum, or the like. The second conductor layer 12 (wiring board 10) is bonded to the heat dissipation base 20 with the first bonding material S1 such as solder. The second conductor layer 12 may be also referred to as a heat dissipation layer, a heat dissipation plate, a heat dissipation pattern, a conductor pattern, or the like.

The first conductor layer 11 is a member that functions as a wiring member in the inverter circuit and is formed of, for example, a metal plate, a metal foil, or the like of copper, aluminum, or the like. The first conductor layer 11 may be also referred to as a conductor plate, a conductor pattern, a conductive layer, a wiring pattern, or the like.

By way of example, as illustrated in FIG. 1, four semiconductor elements 14 and four semiconductor elements 15 are mounted on the first conductor layer 11 side by side in the X direction with the bonding material S such as solder (see FIG. 2).

The semiconductor element 14 is, for example, an insulated gate bipolar transistor (IGBT) which is a switching element, and the semiconductor element 15 is, for example, a free wheeling diode (FWD) element which is a diode element. As the semiconductor element 14 and the semiconductor element 15, another semiconductor element such as a reverse conducting (RC)-IGBT element in which a switching element and a diode element connected in antiparallel to the switching element are integrated may be disposed. The switching element and the diode element in the semiconductor element 14, 15 are not limited to be formed on a Si substrate, and may be formed on a semiconductor substrate using a wide band gap semiconductor such as silicon carbide (SiC) or gallium nitride (GaN), for example. In addition, the switching element of the semiconductor element 14 may include, for example, a metal oxide semiconductor field effect transistor (SiC-MOSFET), a bipolar junction transistor (BJT), or the like. Further, the diode element of the semiconductor element 15 may include, for example, a schottky barrier diode (SiC-SBD), a junction barrier schottky (JBS) diode, a merged PN schottky (MPS) diode, a PN diode, or the like.

The four wiring boards 10 can be the same wiring boards 10 or symmetrical wiring boards 10. For example, the upper left wiring board 10 (on the positive side in the Y direction and the negative side in the X direction) in FIG. 1 preferably has the same shape as or a symmetrical shape with respect to the upper right wiring board 10 (on the positive side in the Y direction and the positive side in the X direction). In addition, the upper left wiring board 10 in FIG. 1 can be formed by rotating a wiring board having the same shape as or a symmetrical shape with respect to the lower left wiring board 10 (on the negative side in the Y direction and the negative side in the X direction) in FIG. 1 or the lower right wiring board 10 (on the negative side in the Y direction and the positive side in the X direction) in FIG. 1 by 180 degrees in plan view.

The main electrodes provided on the upper surfaces of the semiconductor elements 14 and 15 are connected to the other semiconductor elements 14 and 15, the first conductor layer 11, or an input terminal (not illustrated) by main current wiring W1. For example, the semiconductor module 1 includes two first input terminals (E terminals), two second input terminals (C terminals), and an auxiliary input terminal (C terminal, E terminal), and these terminals may function as terminals (C, E) constituting a common set of circuits as in the circuit diagram illustrated in FIG. 5, or may function as terminals (C1, C2, E1, E2) constituting two sets of circuits as in the circuit diagram illustrated in FIG. 6. In addition, a control electrode (for example, a gate electrode) provided on the upper surfaces of the semiconductor elements 14 and 15 is indirectly or directly connected to a control terminal (G) (not illustrated) via the first conductor layer 11 by control wiring W2. Preferably, the input terminal and the control terminal are, for example, integrally fixed to a case (not illustrated) that covers the periphery of the four wiring boards 10. In addition, as illustrated in FIG. 1, at four corners A1 of a wiring board region A including the entire area of the four wiring boards 10 including the four wiring boards 10 (that is, the smallest rectangular region surrounding all the wiring boards 10 in plan view), the first conductor layer 11 (connected to the control terminal) is connected to only the control wiring W2 and not connected to the main current wiring W1. At the four corners A1, a main current does not flow through the first conductor layer 11.

As illustrated in FIG. 1, the heat dissipation base 20 has a rectangular shape in plan view, and fastening holes 23 into which the screws 120 are inserted are provided at a total of six locations, that is, four locations of the four corner portions and two locations of the center portions in the X direction at both ends in the Y direction. Preferably, the corner portion of the heat dissipation base 20 in plan view is R-chamfered. In addition, preferably, the corner portion of the wiring board 10 in plan view is C-chamfered.

The heat dissipation base 20 is a member that functions as a heat conducting member that conducts heat generated by the semiconductor elements 14 and 15 to the cooler 110, and is formed of a metal plate such as a copper plate or an aluminum plate, for example. For example, the entire second surface 22 of the heat dissipation base 20 is warped such that the second surface 22 becomes a convex curved surface by warping a flat plate-shaped metal plate through press working or the like. As a result, regarding a vertical gap between the heat dissipation base 20 and the cooler 110 illustrated in FIG. 2, a gap G2 at a peripheral portion in plan view is larger than a gap G1 at the center portion in plan view particularly before the heat dissipation base 20 is attached to the cooler 110 with the screw 120. The heat conductive material C is interposed between the heat dissipation base 20 and the cooler 110.

The shape, the arrangement number, the arrangement location, and the like of the wiring board 10 of the semiconductor elements 14 and 15 or the like in the semiconductor module 1 can be appropriately changed. For example, the number of wiring boards 10 is not limited to four, and may be any number of two or more. The plurality of wiring boards 10 may be aligned only in one direction (X direction or Y direction). In addition, the layout of the first conductor layer 11 as the wiring member provided on the upper surface side of the wiring board 10 is changed according to the type, the shape, the arrangement number, the arrangement location, and the like of the semiconductor element 14, 15. The main current wiring W1 and the control wiring W2 in the semiconductor module 1 described above are, for example, metallic bonding wires, but some or all of the main current wiring W1 and the control wiring W2 may be replaced with, for example, leads formed by processing a metal plate such as a copper plate.

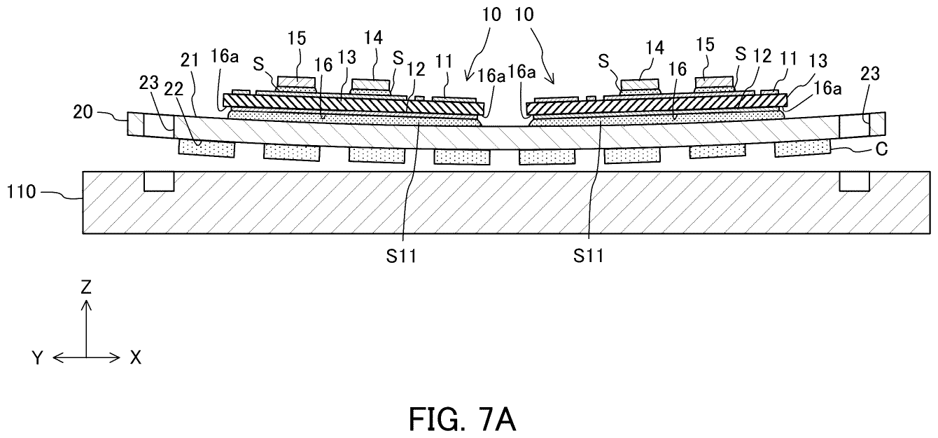

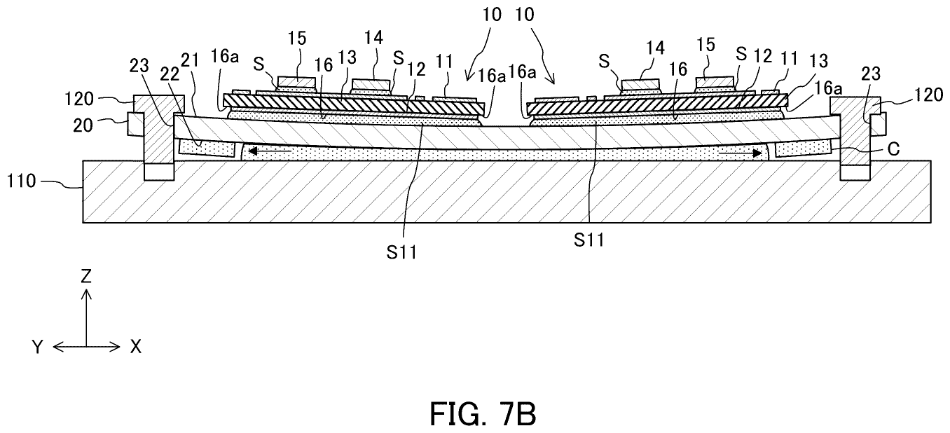

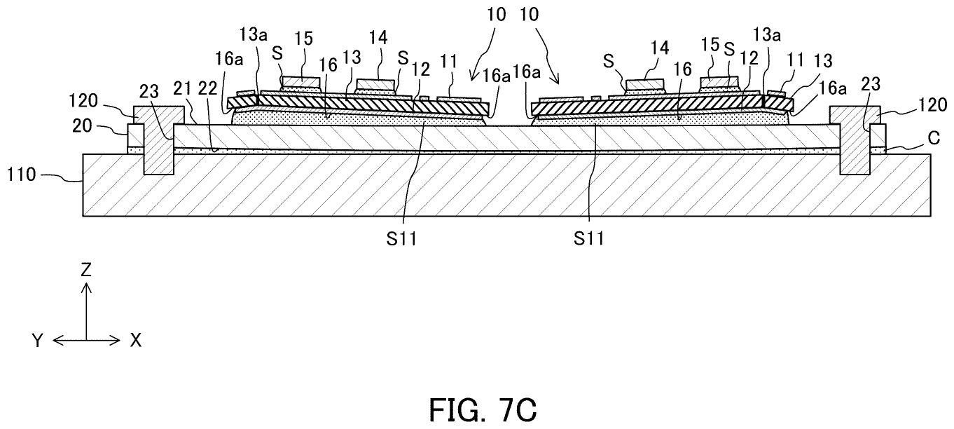

Here, with reference to FIGS. 7A to 7C, a semiconductor module in a comparative example will be described in which the wiring board 10 is damaged when the heat dissipation base 20 is attached to the cooler 110. FIGS. 7A to 7C are sectional views at a position corresponding to the sectional view taken along line II-II in FIG. 1.

To improve adhesion between the heat dissipation base 20 and the cooler 110 with the heat conductive material C such as thermal grease, for example, as illustrated in FIG. 7A, a plurality of heat conductive materials C are disposed so as to be scattered on the second surface 22 of the heat dissipation base 20 before being attached to the cooler 110. Before the heat dissipation base 20 is attached to the cooler 110, the four wiring boards 10 are sealed by sealing resin (gel) (not illustrated).

The second surface 22 of the heat dissipation base 20 is warped so as to become a convex curved surface, that is, such that the vertical position becomes on the upper side at the peripheral edge and on the lower side at the center portion. Thus, when the heat dissipation base 20 is disposed on the cooler 110, the heat conductive material C disposed at the center of the second surface 22 of the heat dissipation base 20 first comes into contact with the upper surface of the cooler 110. Thereafter, when the heat dissipation base 20 is pressed against the cooler 110 when the screw 120 is fastened, as illustrated in FIG. 7B, the heat conductive material C is integrated between the second surface 22 of the heat dissipation base 20 and the upper surface of the cooler 110 while radially expanding from the center of the second surface 22. At this time, since the second surface 22 of the heat dissipation base 20 is formed to be a convex curved surface, the heat conductive material C easily spreads radially from the center of the second surface 22 of the heat dissipation base 20, and thus a gap is hardly generated in the integrated heat conductive material C.

Before the heat dissipation base 20 is attached to the cooler 110, a plurality of wiring boards 10 are bonded to the heat dissipation base 20. When the heat dissipation base 20 is attached to the cooler 110, the heat conductive material C is spread between the heat dissipation base 20 and the cooler 110 as described above, and then the heat dissipation base 20 is fixed to the cooler 110 using the screw 120.

Thus, the heat dissipation base 20 deforms such that the convex curved surface of the second surface 22 becomes a curved surface close to a flat surface. That is, when the heat dissipation base 20 is attached to the cooler 110 with the screw 120, the heat dissipation base 20 deforms in a direction in which a warpage becomes smaller than that before the attachment. When the heat dissipation base 20 deforms in the direction in which the warpage becomes smaller, deformation stress is applied to the wiring board 10 bonded to the first surface 21 of the heat dissipation base 20, and for example, stress concentrates at the slit between the first conductor layers 11 in the vicinity of the screw 120 (or the peripheral edge of the first conductor layer 11) (stress concentration portion 13a illustrated in FIG. 7C), and damage to the wiring board 10 such as cracking of the insulating layer 13 occurs.

In the above-described comparative example, the bonding surface 16 of the wiring board 10 to the heat dissipation base 20 has only a first corner portion 16a bonded to the heat dissipation base 20 with a first bonding material S11. That is, the four corners of the bonding surface 16 are all the first corner portion 16a bonded to the heat dissipation base 20.

On the other hand, in the first embodiment, as indicated by the broken line in FIG. 1, the first bonding material S1 does not reach the four corners A1 of the wiring board region A, and the bonding surface 16 of the wiring board 10 has a second corner portion 16b that is not bonded to the heat dissipation base 20 with the first bonding material S1 only at the four corners A1 of the wiring board region A. At the second corner portion 16b illustrated in FIG. 2, not only the first bonding material S1 but also the second conductor layer 12 is missing. The above-described sealing resin for sealing the wiring board 10 enters the missing portion. The missing portion of the second conductor layer 12 can be formed by, for example, etching. The remaining three corner portions of the bonding surface 16 of the wiring board 10 are preferably the first corner portion 16a bonded to the heat dissipation base 20 with the first bonding material S1. If there are relatively wide and narrow regions that are not bonded to the heat dissipation base 20 at the corner portions of the bonding surface 16, the corner portion at which the non-bonded region is wide may be regarded as the second corner portion 16b, while the corner portion at which the non-bonded region is narrow may be regarded as the first corner portion 16a. Further, the second corner portion 16b may not be provided at all of the four corners A1 of the wiring board region A, and the second corner portion 16b of one or more wiring boards 10 are only required to be located at the four corners A1.

Here, the local convex portion (the position of the local convex shape) P4 of the second surface 22 of the heat dissipation base 20 will be described. As illustrated in FIG. 3, which represents the change in the warped shape as shading, on the second surface 22 that is the lower surface of the heat dissipation base 20, positions where a diagonal line D connecting the fastening holes 23 (the centers of the fastening holes 23) intersects both ends of a region corresponding to the wiring board region A (a region at the same position as the wiring board region A in plan view) are defined as reference positions P1, P2. An intermediate position between the two reference positions P1 and P2 on the second surface 22 is defined as a center position P3. Since the second surface 22 of the heat dissipation base 20 is warped so as to become a convex curved surface, the diagonal line D can be a line along the curved surface. In addition, the reference positions P1 and P2 may also be referred to as positions where the distance L from the center of the fastening hole 23 is a predetermined distance.

In FIG. 4, the warped shape of the second surface 22 (lower surface) of the heat dissipation base 20 along the diagonal line D is indicated by a black solid line. With a vertical position (concave or convex) at the reference position P1 (P2) as an origin, the protrusion amount is large (convex) in the upper part and the protrusion amount is small (concave) in the lower part in FIG. 4.

Then, an auxiliary line (gray dotted line) connecting the position of the warped shape at the center position P3 and the reference positions P1 and P2 is drawn. In addition, a difference between the warped shape and the auxiliary line is defined as an auxiliary height curve (gray solid line). A position on the diagonal line D where the protrusion amount of the auxiliary height curve is the largest (peak convex position) is defined as the local convex portion P4. The local convex portion P4 may also be obtained along the other diagonal line intersecting the diagonal line D, and both may be defined as the local convex portion P4, or only the one having the larger protrusion amount may be defined as the local convex portion P4. In FIG. 1, the local convex portion P4 is illustrated on the upper right wiring board 10 in FIG. 1. The first bonding material S1 is preferably located closer to the center position P3 than the local convex portion P4. That is, the first bonding material S1 is preferably located close to the center position P3 at a distance from the local convex portion P4 of the heat dissipation base 20. As the local convex portion P4 gets closer to the slit between the first conductor layers 11 (or the peripheral edge of the first conductor layer 11) in the vicinity of the screw 120 where stress tends to concentrate, stress applied to the slit increases.

In the first embodiment described above, the semiconductor module 1 includes the plurality of wiring boards 10 on which the semiconductor elements 14 and 15 are mounted, the heat dissipation base 20, and the first bonding material S1. The heat dissipation base 20 has the first surface 21 to which the plurality of wiring boards 10 are bonded, and the second surface 22 located on the opposite side of the first surface 21. The first bonding material S1 bonds the plurality of wiring boards 10 to the heat dissipation base 20. The heat dissipation base 20 is warped such that the second surface 22 becomes a convex curved surface. The fastening hole 23 is provided at least at the plurality of corner portions of the heat dissipation base 20. The bonding surface 16 of the wiring board 10 of each of the plurality of wiring boards 10 facing the heat dissipation base 20 includes the first corner portion 16a bonded to the heat dissipation base 20 with the first bonding material S1 and the second corner portion 16b not bonded to the heat dissipation base 20 with the first bonding material S1. The first bonding material S1 bonds the plurality of wiring boards 10 to the heat dissipation base 20 such that the second corner portion 16b of the wiring board 10 is located at the four corners A1 of the wiring board region A including the entire area of the plurality of wiring boards 10.

As a result, when the heat dissipation base 20 is attached to the cooler 110 or the like, even if the second surface 22 of the heat dissipation base 20 deforms in a direction in which the convex curved surface changes to a flat surface, the wiring board 10 does not follow the deformation of the heat dissipation base 20 in the vicinity of the fastening hole 23 because the wiring board 10 is not bonded to the heat dissipation base 20 at the second corner portion 16b of the four corners A1 of the wiring board region A, thus making it possible to suppress the concentration of stress on the wiring board 10. In addition, it is possible to secure the heat dissipation performance from the wiring board 10 to the heat dissipation base 20 at the first corner portion 16a as compared with an aspect in which the wiring board 10 has the second corner portion 16b at all the corners other than the four corners A1 of the wiring board region A. Therefore, according to the first embodiment, it is possible to prevent the damage of the wiring board 10 due to the deformation of the heat dissipation base 20 when it is fastened, while securing the heat dissipation performance. When the corner portions of the bonding surface 16 of the wiring board 10 are all the first corner portion 16a, a horizontal crack occurs on the insulating layer 13 of the wiring board 10 in the direction intersecting the diagonal line D at a rate of 5% when the heat dissipation base 20 is attached (fastened) to the cooler 110, and thus the wiring board 10 fails (is damaged). However, as in the first embodiment, the rate of the failure of the semiconductor module 1 becomes 0% when the second corner portion 16b is provided only at the four corners A1 of the wiring board region A.

In the first embodiment, the wiring board 10 includes the insulating layer 13, the first conductor layer 11 provided on the surface on the semiconductor element 14, 15 side of the insulating layer 13, and on the second conductor layer 12 provided on the heat dissipation base 20 side of the surface of the insulating layer 13. The second conductor layer 12 is missing at the second corner portion 16b.

As a result, even if the first bonding material S1 protrudes to the second corner portion 16b, the first bonding material S1 is not bonded to the insulating layer 13, and thus it is possible to prevent damage to the wiring board 10 more reliably. In addition, the amount of material used for the second conductor layer 12 can be reduced.

In the first embodiment, the semiconductor module 1 includes the main current wiring W1 and the control wiring W2, and, at the four corners A1 of the wiring board region A, the first conductor layer 11 is connected to only the control wiring W2 and not connected to the main current wiring W1 and thus a main current does not flow.

As a result, at the second corner portion 16b of the bonding surface 16 (the four corners A1 of the wiring board region A) where the wiring board 10 and the heat dissipation base 20 are not bonded to each other, the wiring board 10 is not subject to a high temperature, which can avoid impairing the heat dissipation performance.

In the first embodiment, when the positions where the diagonal line D connecting the fastening holes 23 intersects both ends of the region corresponding to the wiring board region A are defined as the reference positions P1 and P2 and the intermediate position between the two reference positions P1 and P2 is defined as the center position P3, the heat dissipation base 20 has, on the second surface (lower surface) 22, the local convex portion P4 that is the position where the protrusion amount of the convex curved surface from the auxiliary line connecting the two reference positions P1 and P2 and the center position P3 is the largest. The first bonding material S1 is located close to the center position P3 at a distance from the local convex portion P4 of the heat dissipation base 20.

As a result, since the wiring board 10 does not follow the deformation of the heat dissipation base 20 at the local convex portion P4 where stress tends to concentrate on the wiring board 10, it is possible to more reliably suppress the concentration of stress on the wiring board 10.

### Modification of First Embodiment

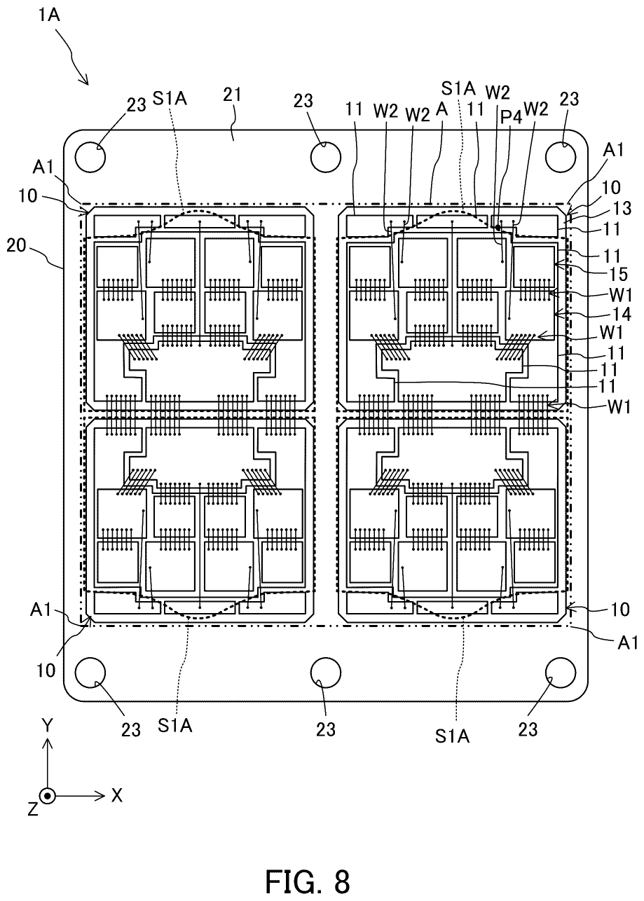

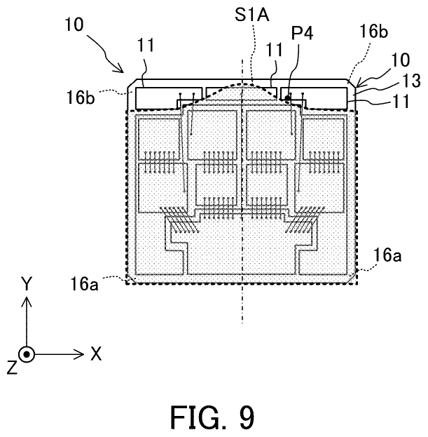

FIG. 8 is a plan view illustrating a semiconductor module 1A according to a modification of the first embodiment. FIG. 9 is a plan view illustrating a first bonding material S1A of the wiring board 10 in a see-through manner.

In the semiconductor module 1A according to the present modification, the second corner portion 16b where the wiring board 10 and the heat dissipation base 20 are not bonded to each other with the first bonding material S1A is provided not only at the four corners A1 of the wiring board region A but also in the vicinity of the two fastening holes 23 at the center portion in the X direction. Other matters can be similar to those described above, and thus the description thereof will be omitted.

As illustrated in FIGS. 8 and 9, the bonding surface 16 of the wiring board 10 has the second corner portion 16b where the wiring board 10 and the heat dissipation base 20 are not bonded to each other at the four corners A1 of the wiring board region A (see FIG. 9). In addition, the bonding surface 16 also has the second corner portion 16b at one corner portion adjacent (across one side) to the second corner portion 16b at the four corners A1 of the wiring board region A. On the other hand, the bonding surface 16 has the first corner portion 16a where the wiring board 10 and the heat dissipation base 20 are bonded to each other at the remaining two corner portions adjacent to each other.

The second corner portion 16b at a position different from the four corners A1 of the wiring board region A is preferably provided at a corner portion in the vicinity of the two fastening holes 23 at the center portion in the X direction. In addition, also at the second corner portion 16b in the present modification, not only the first bonding material S1A but also the second conductor layer 12 is preferably missing. In addition, the first bonding material S1A is preferably located close to the center position P3 at a distance from the local convex portion P4 (see FIG. 3).

The first bonding material S1A is preferably missing in a symmetrical shape at the two second corner portions 16b (in FIG. 8, it is bilaterally symmetrical in all the four wiring boards 10). In the example of FIG. 9, the first bonding material S1A is provided so as to be missing in a symmetrical shape across the center line (one-dot chain line) extending in the Y direction at the center in the X direction.

In the modification of the first embodiment described above, regarding matters similar to those of the first embodiment described above, it is possible to obtain a similar effect, that is, an effect of preventing damage to the wiring board 10 due to the deformation of the heat dissipation base 20 when it is fastened, while securing the heat dissipation performance.

In addition, in the present modification, the bonding surface 16 of the wiring board 10 of each of the plurality of wiring boards 10 includes two first corner portions 16a adjacent to each other and two second corner portions 16b adjacent to each other, and the first bonding material S1A is missing in a symmetrical shape at the two second corner portions 16b.

As a result, for example, when four (a plurality of) wiring boards 10 are in the same shape or when each of the wiring boards 10 is a symmetrical shape, not only the wiring board 10 but also the first bonding material S1A can be in the same shape or in a symmetrical shape. In addition, the first bonding material S1A is disposed easily as compared with an aspect in which the first bonding material S1A is missing in an asymmetrical shape at the two second corner portions 16b.

### Second Embodiment

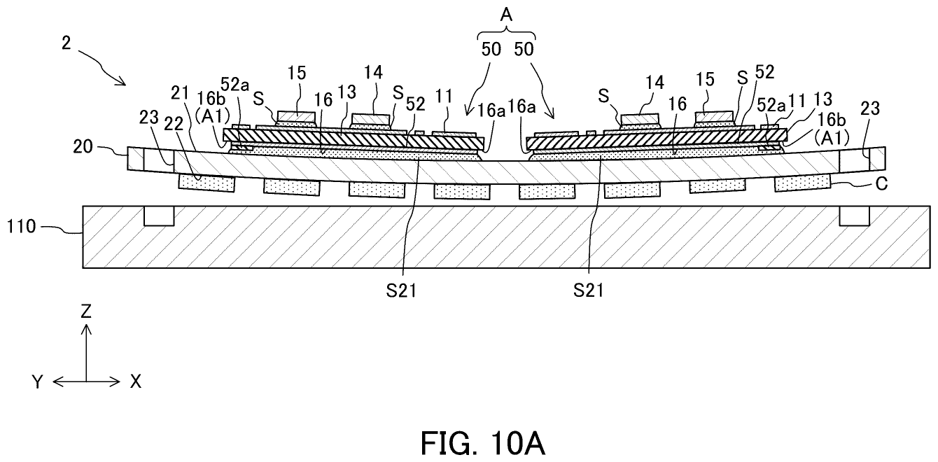

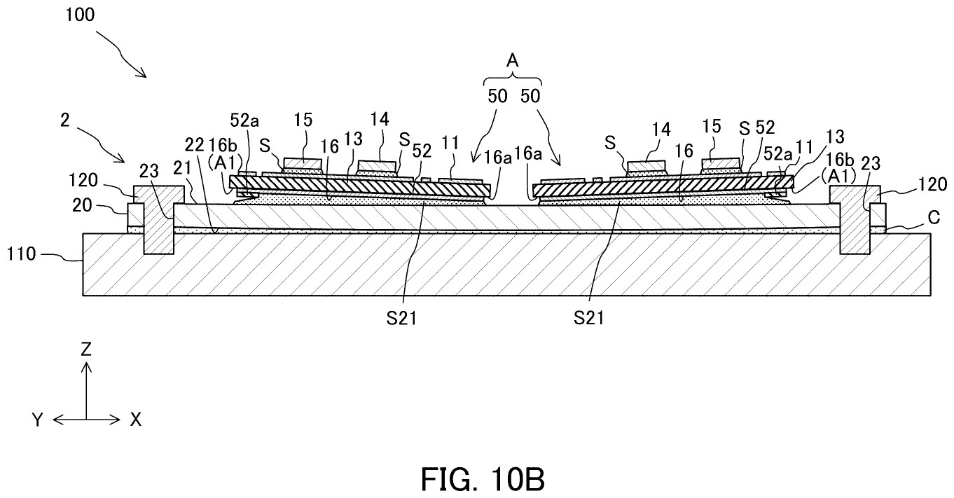

FIGS. 10A and 10B are sectional views illustrating a semiconductor module 2 according to a second embodiment at a position corresponding to the sectional view taken along line II-II in FIG. 1.

In the semiconductor module 2 according to the second embodiment, a second conductor layer 52 of a wiring board 50 has a solder resist 52a provided at the second corner portion 16b. The other matters can be similar to those of the first embodiment described above, and thus the same reference numerals as those of the first embodiment described above are given to FIGS. 10A and 10B, and the description thereof will be omitted, except for the wiring board 50, the second conductor layer 52, the solder resist 52a, and a first bonding material S21.

As illustrated in FIG. 10A, the second conductor layer 52 has the solder resist 52a at the second corner portion 16b where the wiring board 50 and the heat dissipation base 20 are not bonded to each other with the first bonding material S21. The solder resist 52a is an example of a non-bonded processed portion (a layer or a surface that is formed in a non-bonded area and that prevents the first bonding material from entering the non-bonded area) applied to the second conductor layer 52. The non-bonded processed portion is not limited to the solder resist 52a as long as it is a processed portion that prevents bonding between the second conductor layer 52 (wiring board 50) and the heat dissipation base 20 with the first bonding material S21.

The solder resist 52a has a property of repelling the first bonding material S21 even when coming into contact with the first bonding material S21, and thus is not bonded to the heat dissipation base 20. Thus, when the heat dissipation base 20 is attached to the cooler 110 with the screw 120 as illustrated in FIG. 10B, the wiring board 50 does not follow the deformation of the heat dissipation base 20 at the second corner portion 16b in the vicinity of the fastening hole 23 even if the second surface 22 of the heat dissipation base 20 deforms in a direction in which the convex curved surface changes to a flat surface. Therefore, a vertical gap is generated between the solder resist 52a and the first bonding material S21.

In the second modification, as in the modification of the first embodiment, the bonding surface 16 of the wiring board 50 of each of the plurality of wiring boards 50 includes two first corner portions 16a adjacent to each other and two second corner portions 16b adjacent to each other, and the first bonding material S21 may be missing in a symmetrical shape at the two second corner portions 16b.

In the second embodiment described above, regarding matters similar to those of the first embodiment described above, it is possible to obtain a similar effect, that is, an effect of preventing damage to the wiring board 50 due to the deformation of the heat dissipation base 20 when it is fastened, while securing the heat dissipation performance.

In addition, in the second embodiment, the second conductor layer 52 of the wiring board 50 includes the solder resist 52a (an example of a non-bonded processed portion) applied to the second corner portion 16b that is not bonded to the heat dissipation base 20 with the first bonding material S21.

As a result, the solder resist 52a (wiring board 50) is not bonded to the heat dissipation base 20 at the second corner portion 16b of the wiring board 50 located at the four corners A1 of the wiring board region A in FIG. 1, and thus the wiring board 50 does not follow the deformation of the heat dissipation base 20 in the vicinity of the fastening hole 23. Therefore, even if the first bonding material S21 is located at the second corner portion 16b, the wiring board 50 and the heat dissipation base 20 are not bonded to each other through simple processing using the solder resist 52a without missing the second conductor layer 52 at the second corner portion 16b, which can prevent damage to the wiring board 50 more reliably.

The solder resist 52a may be disposed so as to surround the second conductor layer 52 on the entire back surface of the wiring board 50 where the second conductor layer 52 is not present. In this case, the portion to be bonded to the first bonding material S21 can be reliably controlled. In particular, when the solder resist 52a is disposed only at the boundary between the second corner portion 16b and the region to be bonded to the first bonding material S21, the first bonding material S21 gets over the solder resist 52a and is disposed at the second corner portion 16b, and thus the second corner portion 16b and the heat dissipation base 20 may be bonded to each other. It is desirable to cover the entire vicinity of the second corner portion 16b with the solder resist 52a so that the first bonding material S21 does not get over the solder resist 52a and come to the vicinity of the second corner portion 16b.

### Third Embodiment

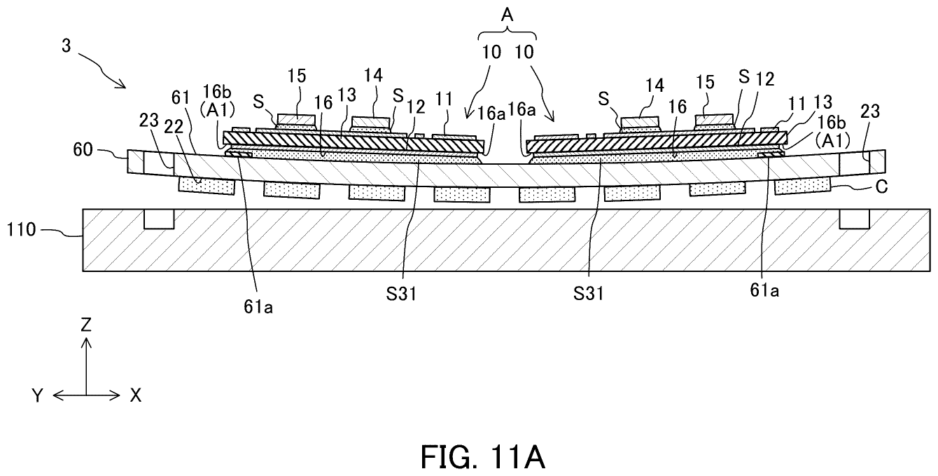

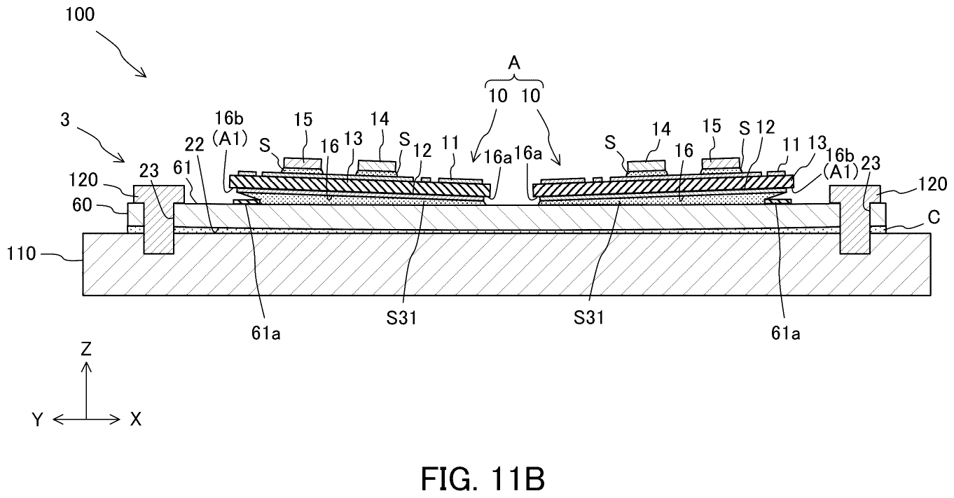

FIGS. 11A and 11B are sectional views illustrating a semiconductor module 3 according to a third embodiment at a position corresponding to the sectional view taken along line II-II in FIG. 1.

In the semiconductor module 3 according to the third embodiment, a heat dissipation base 60 has a solder resist 61a in a region of a first surface 61 facing the second corner portion 16b. The other matters can be similar to those of the first embodiment described above, and thus the same reference numerals as those of the first embodiment described above are given to FIGS. 11A and 11B, and the description thereof will be omitted, except for the heat dissipation base 60, the first surface 61, the solder resist 61a, and a first bonding material S31.

As illustrated in FIG. 11A, the first surface 61 has the solder resist 61a in the region facing the second corner portion 16b where the wiring board 10 and the heat dissipation base 60 are not bonded to each other with the first bonding material S31. The solder resist 61a is an example of a non-bonded processed portion applied to the first surface 61 of the heat dissipation base 60. The non-bonded processed portion is not limited to the solder resist 61a as long as it is a processed portion that prevents bonding between the heat dissipation base 60 and the wiring board 10 with the first bonding material S31. For example, the first bonding material S31 is less likely to enter a portion painted with a pencil on the first surface 61 of the heat dissipation base 60, and thus, if the painting with the pencil is performed to prevent the first bonding material S31 from entering the second corner portion 16b, this processed portion functions as the non-bonded processed portion.

The solder resist 61a is not bonded to the wiring board 10 even if it is in contact with the first bonding material S31. Thus, when the heat dissipation base 60 is attached to the cooler 110 with the screw 120 as illustrated in FIG. 11B, the wiring board 10 does not follow the deformation of the heat dissipation base 60 at the second corner portion 16b in the vicinity of the fastening hole 23 even if the second surface 22 of the heat dissipation base 60 deforms in a direction in which the convex curved surface changes to a flat surface, and a vertical gap is generated between the solder resist 61a and the wiring board 10.

In the third embodiment, as in the modification of the first embodiment, the bonding surface 16 of the wiring board 10 of each of the plurality of wiring boards 10 includes two first corner portions 16a adjacent to each other and two second corner portions 16b adjacent to each other, and the first bonding material S31 may be missing in a symmetrical shape at the two second corner portions 16b. In addition, in the third embodiment, as in the second embodiment, a non-bonded processed portion (solder resist 52a of the second conductor layer 52 illustrated in FIGS. 10A and 10B) may be provided on the second conductor layer 12.

In the third embodiment described above, regarding matters similar to those of the first embodiment described above, it is possible to obtain a similar effect, that is, an effect of preventing damage to the wiring board 10 due to the deformation of the heat dissipation base 60 when it is fastened, while securing the heat dissipation performance.

In addition, in the third embodiment, the heat dissipation base 60 has the solder resist 61a (an example of the non-bonded processed portion) applied to the region of the first surface 61 facing the second corner portion 16b.

As a result, the solder resist 61a (heat dissipation base 60) is not bonded to the wiring board 10 at the second corner portion 16b of the wiring board 10 located at the four corners A1 of the wiring board region A in FIG. 1, and thus the wiring board 10 does not follow the deformation of the heat dissipation base 60 in the vicinity of the fastening hole 23. Therefore, even if the first bonding material S31 is located at the second corner portion 16b, the wiring board 10 and the heat dissipation base 60 are not bonded to each other through simple processing using the solder resist 61a without missing the second conductor layer 12 at the second corner portion 16b, which can prevent damage to the wiring board 10 more reliably.

Similarly, the solder resist 61a may be disposed so as to surround the second conductor layer 12 on the heat dissipation base 60 facing a portion of the back surface of the wiring board 10 where the second conductor layer 12 is not present. In this case, the portion to be bonded to the first bonding material S31 can be reliably controlled. In particular, when the solder resist 61a is disposed only at the boundary between the second corner portion 16b and the region to be bonded to the first bonding material S31, the first bonding material S31 may get over the solder resist 61a and be disposed at the second corner portion 16b, and thus the second corner portion 16b and the heat dissipation base 60 may be bonded to each other. It is desirable to cover the entire vicinity of the second corner portion 16b with the solder resist 61a so that the first bonding material S31 does not get over the solder resist 61a and come to the vicinity of the second corner portion 16b. The matter regarding the solder resist 61a also applies to the painting with a pencil (application of graphite).

### Fourth Embodiment

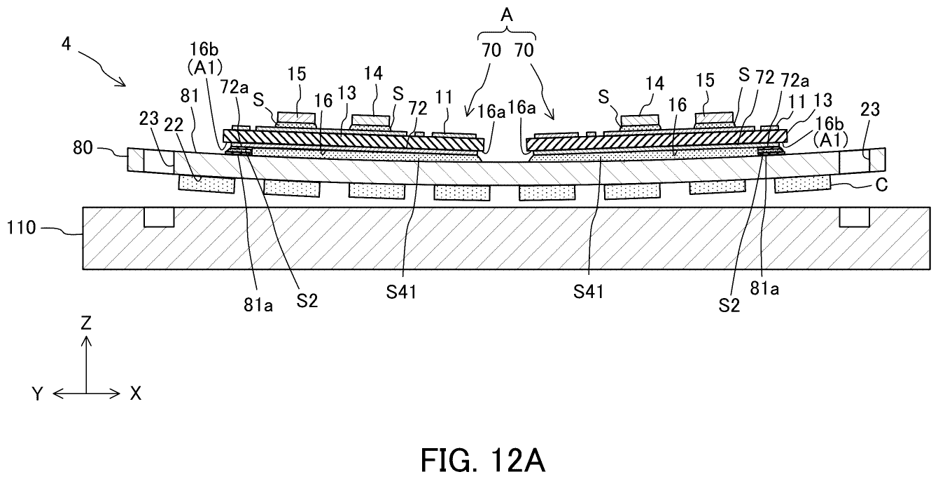

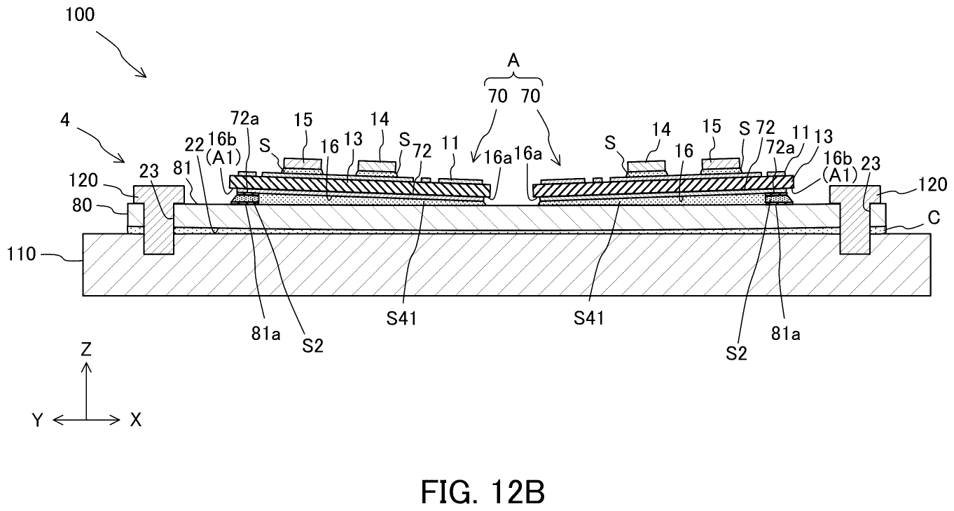

FIGS. 12A and 12B are sectional views illustrating a semiconductor module 4 according to a fourth embodiment at a position corresponding to the sectional view taken along line II-II in FIG. 1.

In the semiconductor module 4 according to the fourth embodiment, at the second corner portion 16b where a wiring board 70 and a heat dissipation base 80 are not bonded to each other with a first bonding material S41, the plurality of wiring boards 70 and the heat dissipation base 80 are bonded to each other with a second bonding material S2 having more elasticity than the first bonding material S41. The other matters can be similar to those of the first embodiment described above, and thus the same reference numerals as those of the first embodiment described above are given to FIGS. 12A and 12B, and the description thereof will be omitted, except for the wiring board 70, a second conductor layer 72, a solder resist 72a, the heat dissipation base 80, a first surface 81, a solder resist 81a, and the first bonding material S41.

As illustrated in FIG. 12A, the solder resists 72a and 81a are provided on the second conductor layer 72 and the first surface 81 of the heat dissipation base 80, respectively, as an example of a non-bonded processed portion at the second corner portion 16b where the wiring board 70 and the heat dissipation base 80 are not bonded to each other with the first bonding material S41. Then, the second bonding material S2 is disposed between the solder resists 72a and 81a.

The solder resists 72a and 81a are not bonded to the first bonding material S41, and the first bonding material S41 hardly enters between the solder resists 72a and 81a. Thus, the second bonding material S2 is preferably inserted between the solder resists 72a and 81a after the first bonding material S41 is disposed and before the sealing resin is injected. The second bonding material S2 has more elasticity than the first bonding material S41 so that the wiring board 70 does not follow the deformation of the heat dissipation base 80. Note that the second bonding material S2 preferably has a higher thermal conductivity than the sealing resin.

When the heat dissipation base 80 is attached to the cooler 110 with the screw 120 as illustrated in FIG. 12B, the second bonding material S2 stretches at the second corner portion 16b and the wiring board 70 hardly follows the deformation of the heat dissipation base 80 in the vicinity of the fastening hole 23 even if the second surface 22 of the heat dissipation base 80 deforms in a direction in which the convex curved surface changes to a flat surface.

In the fourth embodiment, as in the modification of the first embodiment, the bonding surface 16 of the wiring board 70 of each of the plurality of wiring boards 70 includes two first corner portions 16a adjacent to each other and two second corner portions 16b adjacent to each other, and the first bonding material S41 may be missing in a symmetrical shape at the two second corner portions 16b. In this case, the second bonding material S2 is preferably provided at least at the second corner portion 16b of the four corners A1 of the wiring board region A. In the fourth embodiment, the solder resists 72a and 81a are provided on the wiring board 70 and the heat dissipation base 80, but the solder resists 72a and 81a can be omitted as long as the first bonding material S41 can be disposed so as not to enter the second corner portion 16b.

In the fourth embodiment described above, regarding matters similar to those of the first embodiment described above, it is possible to obtain a similar effect, that is, an effect of preventing damage to the wiring board 70 due to the deformation of the heat dissipation base 80 when it is fastened, while securing the heat dissipation performance.

In addition, in the fourth embodiment, the semiconductor module 4 further includes the second bonding material S2 that bonds the plurality of wiring boards 70 to the heat dissipation base 80 at the second corner portion 16b and has more elasticity than the first bonding material S41.

As a result, the wiring board 70 hardly follows the deformation of the heat dissipation base 80 at the second corner portion 16b in the vicinity of the fastening hole 23 of the wiring board 70 located at the four corners A1 of the wiring board region A in FIG. 1. Therefore, it is possible to prevent damage to the wiring board 70 with a simple configuration in which the second conductor layer 12 is not missing. In addition, when the second bonding material S2 has a higher thermal conductivity than the sealing resin, it is possible to enhance the heat dissipation performance from the wiring board 70 to the heat dissipation base 80 at the second corner portion 16b.

The semiconductor modules 1 to 4 according to the first to fourth embodiments are not limited to the above description, and various changes, substitutions, and modifications may be made without departing from the spirit of the technical idea. Further, when the technical idea can be realized in another manner by the progress of the technology or another derived technology, the technical idea may be carried out by using a method thereof. Therefore, the claims cover all embodiments that may be included within the scope of the technical idea.

Hereinafter, some inventions described herein and the drawings are described.

### Supplementary Note 1

A semiconductor module including:
a plurality of wiring boards on which a semiconductor element is mounted;
a heat dissipation base having a first surface to which the plurality of wiring boards are bonded and a second surface located on an opposite side of the first surface; and
a first bonding material that bonds the plurality of wiring boards to the heat dissipation base,
wherein the heat dissipation base is warped such that the second surface becomes a convex curved surface,
a fastening hole is provided at least at a plurality of corner portions of the heat dissipation base,
a bonding surface of the wiring board of each of the plurality of wiring boards facing the heat dissipation base includes a first corner portion bonded to the heat dissipation base with the first bonding material and a second corner portion not bonded to the heat dissipation base with the first bonding material, and
the first bonding material bonds the plurality of wiring boards to the heat dissipation base such that the second corner portion of the wiring board is located at four corners of a wiring board region including the entire plurality of wiring boards.

### Supplementary Note 2

The semiconductor module according to supplementary note 1, wherein
the wiring board includes an insulating layer, a first conductor layer provided on a surface of the insulating layer on the semiconductor element side, and a second conductor layer provided on a surface of the insulating layer on the heat dissipation base side, and
the second conductor layer is missing at the second corner portion.

### Supplementary Note 3

The semiconductor module according to supplementary note 2, wherein
the bonding surface of the wiring board of each of the plurality of wiring boards includes two of the first corner portions adjacent to each other and two of the second corner portions adjacent to each other, and
the first bonding material is missing in a symmetrical shape at the two second corner portions.

### Supplementary Note 4

The semiconductor module according to supplementary note 1, wherein
the wiring board includes an insulating layer, a first conductor layer provided on a surface of the insulating layer on the semiconductor element side, and a second conductor layer provided on a surface of the insulating layer on the heat dissipation base side, and
the second conductor layer has a non-bonded processed portion formed at the second corner portion.

### Supplementary Note 5

The semiconductor module according to supplementary note 1 or 4, wherein
the heat dissipation base has a non-bonded processed portion in a region of the first surface facing the second corner portion.

### Supplementary Note 6

The semiconductor module according to any one of supplementary notes 1 to 5, further including
a second bonding material bonding the plurality of wiring boards and the heat dissipation base at the second corner portion and having more elasticity than the first bonding material.

### Supplementary Note 7

The semiconductor module according to any one of supplementary notes 1 to 6, further including
main current wiring and control wiring,
wherein the wiring board includes an insulating layer, a first conductor layer provided on a surface of the insulating layer on the semiconductor element side, and a second conductor layer provided on a surface of the insulating layer on the heat dissipation base side, and,
at the four corners of the wiring board region, the first conductor layer is connected to only the control wiring and not connected to the main current wiring and thus a main current does not flow.

### Supplementary Note 8

The semiconductor module according to any one of supplementary notes 1 to 7, wherein,
when positions where a diagonal line connecting the fastening holes intersects both ends of a region corresponding to the wiring board region are defined as reference positions and an intermediate position between the two reference positions is defined as a center position, the heat dissipation base has, on the second surface, a local convex portion that is a position where a protrusion amount of the convex curved surface from an auxiliary line connecting the two reference positions and the center position is the largest,
and the first bonding material is located on the center position side at a distance from the local convex portion of the heat dissipation base.

As described above, the present invention has an effect of preventing damage to the wiring board due to the deformation of the heat dissipation base when it is fastened, while securing the heat dissipation performance, and in particular, is useful for industrial or electrical inverter devices.

What is claimed is:

1. A semiconductor module, comprising:
a plurality of semiconductor elements;
a plurality of wiring boards each having an element surface and a bonding surface opposite thereto, the element surface of each wiring board having at least one of the plurality of semiconductor elements is mounted thereon;
a heat dissipation base having a first surface to which the bonding surface of each wiring board is bonded and a second surface opposite to the first surface; and
a first bonding material that bonds the bonding surface of each wiring board to the first surface of the heat dissipation base, wherein
the heat dissipation base is warped such that the second surface thereof becomes convex in a direction away from the plurality of semiconductor elements,
the heat dissipation base has a plurality of corner portions, at least some of which each have a fastening hole,
the first surface of the heat dissipation base has a rectangular wiring board area with four corner portions, and all the plurality of wiring boards are bonded in the wiring board area so that the plurality of wiring boards include a plurality of corner wiring boards that are respectively disposed at at least one of the four corner portions of the wiring board area,
each wiring board has a plurality of corner portions,
the plurality of corner wiring boards includes a plurality of first corner portions that are bonded to the first surface of the heat dissipation base with the first bonding material and four second corner portions that are not bonded to the bonding surface of the heat dissipation base,
the plurality of corner wiring boards is disposed in the wiring board area such that the four second corner portions are respectively located at positions corresponding to respective ones of the four corners of the wiring board area.

2. The semiconductor module according to claim 1, wherein
each wiring board includes an insulating layer having a first surface and a second surface opposite to each other, a first conductor layer provided between the first surface of the insulating layer and the semiconductor element, and a second conductor layer provided on the second surface of the insulating layer and facing the heat dissipation base, and
the four second corner portions of the plurality of corner wiring boards are free of the second conductor layer.

3. The semiconductor module according to claim 2, wherein
each of the four second corner portions includes a non-bonded area that is free of the first bonding material, the non-bonded areas of any two of the four second corners that are arranged along one side of the wiring board area form a symmetrical shape.

4. The semiconductor module according to claim 1, wherein
each wiring board includes an insulating layer having a first surface and a second surface opposite to each other, a first conductor layer provided between the first surface of the insulating layer and the semiconductor element, and a second conductor layer provided on the second surface of the insulating layer and facing the heat dissipation base, and
each of the four second corner portions of the plurality of corner wiring boards includes a non-bonded area that is free of the first bonding material and has a layer or a surface that prevents the first bonding material from entering the non-bonded area.

5. The semiconductor module according to claim 1, wherein the heat dissipation base has a plurality of non-bonded areas on the first surface thereof, each of the four second corner portions being faced by one of the plurality of non-bonded areas, the non-bonded areas being free of the first bonding material and each having a layer or a surface that prevents the first bonding material from entering the non-bonded area.

6. The semiconductor module according to claim 1, further comprising
a second bonding material bonding the four second corner portions of the plurality of corner wiring boards to the heat dissipation base and having an elasticity greater than an elasticity of the first bonding material.

7. The semiconductor module according to claim 1, further comprising
main current wiring that carries a main current, and control wiring, wherein
each wiring board includes an insulating layer having a first surface and a second surface opposite to each other, a first conductor layer provided between the first surface of the insulating layer and the semiconductor element, and a second conductor layer provided on the second surface of the insulating layer and facing the heat dissipation base, and
at each of the four corners of the wiring board area of the heat dissipation base, the first conductor layer is connected to the control wiring and not connected to the main current wiring, whereby the main current does not flow through the first conductor layer.

8. The semiconductor module according to claim 1, wherein,
when positions where a diagonal line connecting two of the fastening holes intersects an outline of the wiring board area are respectively defined as first and second reference points, and a center point of the first and second reference points in the diagonal line is defined as a center point,
the heat dissipation base has, on the second surface thereof, a local convex point that is a point at which a protrusion amount of the second surface from an auxiliary line connecting the first reference point to the center point or the second reference point to the center point is greatest, and
the first bonding material is disposed at a position away from the local convex point toward the center point of the second surface of the heat dissipation base.
